(19) United States
(12) Patent Application Publication
(10) Pub. No.: US 2014/0306780 A1
(43) Pub. Date: Oct. 16, 2014

(54) Duplexers

(71) Applicant: Broadcom Corporation, Irvine, CA (US)

(72) Inventor: Teijo Henrikki LEHTINEN, Helsinki (FI)

(73) Assignee: Broadcom Corporation, Irvine, CA (US)

(21) Appl. No.: 14/250,506

(22) Filed: Apr. 11, 2014

(30) Foreign Application Priority Data
Apr. 12, 2013 (GB) 1306732.7

(51) Int. Cl. H03H 7/46

(52) U.S. Cl. CPC H03H 7/463; H03H 7/461
USPC 333/131; 29/825

(57) ABSTRACT

An electrical balance duplexer comprising an electrical balance load having an electrical balance load connection, an antenna connection, a first differential power amplifier output connection, a second differential power amplifier output connection; and a power combiner configured to combine output power signals from the first differential power amplifier output connection with output power signals from the second differential power amplifier output connection into the antenna connection and into the electrical balance load connection.

### TECHNICAL FIELD

The present invention relates to duplexers. In particular, but not exclusively, the present invention relates to electrical balance duplexers.

### BACKGROUND

FIG. 1 shows a duplexer topology from a paper entitled “An On-Chip Wideband and Low-Loss Duplexer for 3G/4G CMOS Radios” by Mikhemar et al. published in the 2010 Symposium on VLSI Circuits/Technical Digest of Technical Papers. The duplexer of FIG. 1 has at least two severe issues. Firstly, the single-ended power amplifier (PA) output signal couples through the capacitance between the primary and secondary windings of the hybrid balun and causes an enormous common mode signal at the low noise amplifier (LNA) input. The LNA may be designed to have good tolerance for common mode signals, but the required excess LNA linearity may compromise the LNA design, for example in terms of noise figure and/or current consumption. Secondly, if the target is to integrate complementary metal oxide semiconductor (CMOS) PAs to the same die, a differential PA topology is often more suitable for numerous reasons. Most importantly, the supply voltage should be low due to the low breakdown voltage. Transforming the PA load line from 50 Ohm would mean enormous current from a single transistor making the PA efficiency very vulnerable to resistive losses in the output network. Also, high currents require wide connections to avoid electro-migration, and wide connections would mean large parasitic capacitances. The PA in FIG. 1 can be differential and integrated to the same die, but then there has to be a balun before the duplexer, which adds a significant loss.

An alternative duplexer topology is obtained by switching the direction of transmitter (TX) and receiver (RX), which means a differential PA and a single-ended LNA. The LNA can act as an active balun, or there can be an active or passive balun after the single-ended LNA or before a differential LNA. The isolation is then determined primarily by the hybrid transformer, PA common mode rejection ratios (CMRRs), and substrate (ignoring here the leakage through the other circuitry such as power supply, bias, and control lines). Differential PA common mode signals are a result of the mismatch between the plus and minus branches, and result in power loss and potential stability and coupling issues so it is desired to keep these as low as possible. Unfortunately, the PA common mode power to differential power ratio may be large, e.g. −15 decibels (dB). The hybrid transformer CMRR may also be in the order of −15 dB, since good magnetic coupling necessitates that the primary and secondary windings are close together, which then results in capacitance between the primary and secondary windings.

FIG. 2 shows a prior art duplexer topology from a paper entitled “A Tunable Differential Duplexer in 90 nm CMOS” by Abdelhalem et al. published in the 2012 IEEE Radio Frequency Integrated Circuits Symposium. The duplexer of FIG. 2 is a fully differential solution, where capacitively coupled differential PA signals cancels in LNA input, and common mode signals are less harmful for differential LNA. An obvious drawback is the additional balun needed for a single-ended antenna which increases losses.

Usually the required maximum output power from a CMOS PA is obtained by combining the output power of several PA units using a power combiner. Power combiners have substantial loss, thus reducing the total power added efficiency.

### BRIEF DESCRIPTION OF THE DRAWINGS

FIG. 1 shows a duplexer topology according to the prior art;

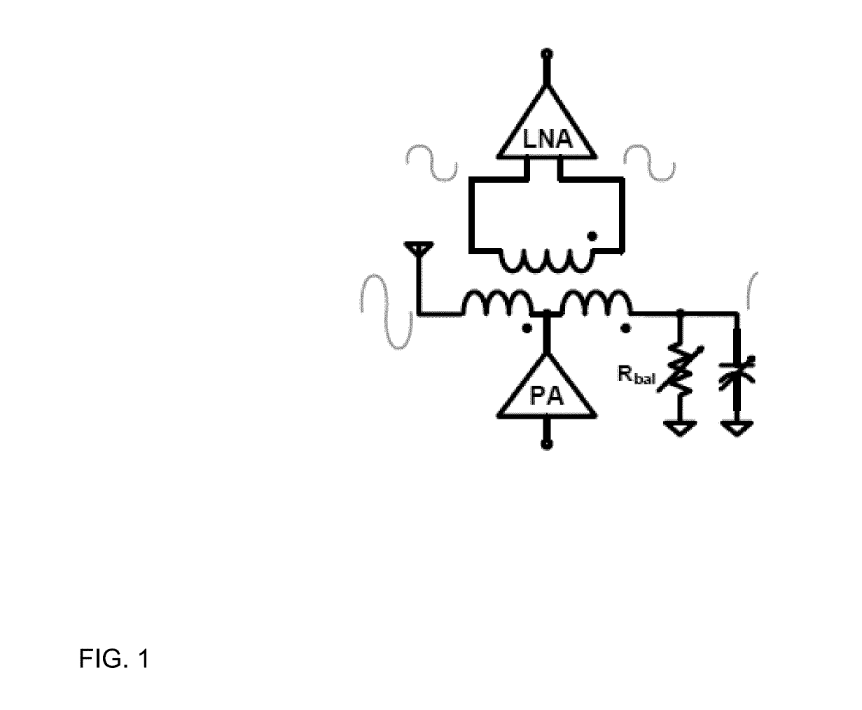

FIG. 2 shows a duplexer topology according to the prior art;

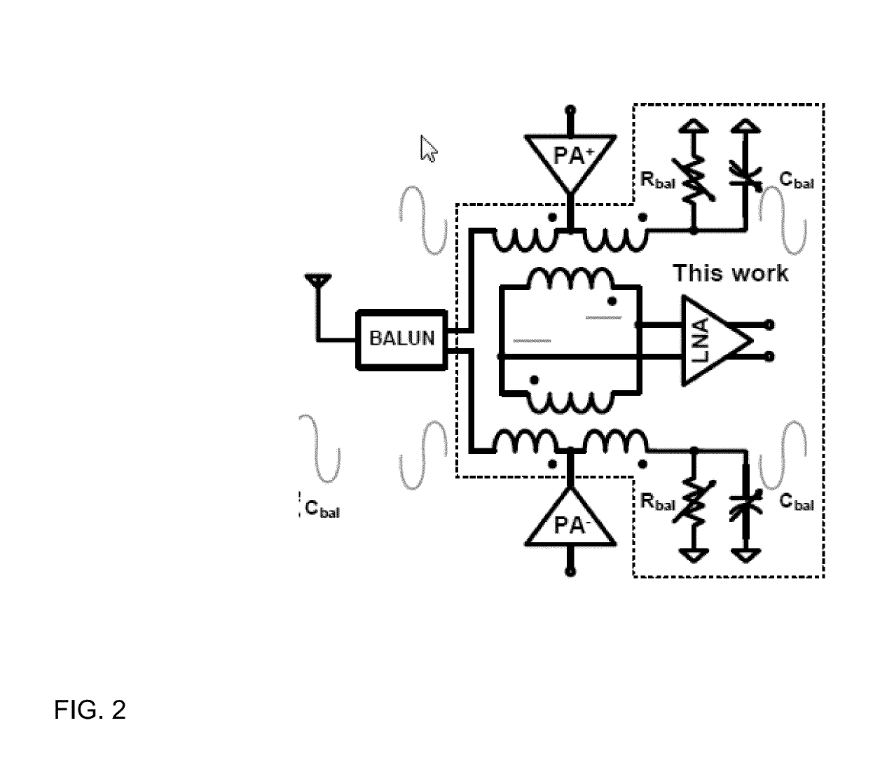

FIG. 3 shows a circuit schematic according to the prior art;

FIG. 4 shows simulation results according to embodiments;

FIG. 5 shows a circuit schematic according to the prior art;

FIG. 6 shows simulation results according to embodiments;

FIG. 7 shows an electrical balance duplexer according to embodiments;

FIG. 8 shows an electrical balance duplexer according to embodiments;

FIG. 9 shows an electrical balance duplexer according to embodiments;

FIG. 10 shows a circuit schematic according to embodiments;

FIGS. 11A and 11B shows simulation results according to embodiments;

FIG. 12 shows an electrical balance duplexer according to embodiments; and

FIG. 13 shows an electrical balance duplexer according to embodiments.

### DETAILED DESCRIPTION

According to a first aspect of the present invention, there is provided an electrical balance duplexer comprising:

an electrical balance load having an electrical balance load connection;

an antenna connection;

a first differential power amplifier output connection;

a second differential power amplifier output connection; and

a power combiner configured to combine output power signals from the first differential power amplifier output connection with output power signals from the second differential power amplifier output connection into the antenna connection and into the electrical balance load connection.

Embodiments comprise a radio frequency (RF) transceiver comprising one or more electrical balance duplexers according to the first aspect of the present invention.

Embodiments comprise a device comprising one or more electrical balance duplexers according to the first aspect of the present invention.

Embodiments comprise a radio-frequency semiconductor integrated circuit (RFIC) comprising one or more electrical balance duplexers according to the first aspect of the present invention.

Embodiments comprise a chipset comprising one or more electrical balance duplexers according to the first aspect of the present invention.

Embodiments comprise a method of operating an electrical balance duplexer according to the first aspect of the present invention.

According to a second aspect of the present invention, there is provided a method of manufacturing an electrical balance duplexer, the method comprising:

providing an electrical balance load having an electrical balance load connection;

providing an antenna connection;

providing a first differential power amplifier output connection;

providing a second differential power amplifier output connection; and

providing a power combiner configured to combine output power signals from the first differential power amplifier output connection with output power signals from the second differential power amplifier output connection into the antenna connection and into the electrical balance load connection.

According to a third aspect of the present invention, there is provided apparatus substantially in accordance with any of the examples as described herein with reference to and illustrated by the accompanying drawings.

According to a fourth aspect of the present invention, there is provided an electrical balance duplexer comprising:

an electrical balance load connection;

an antenna connection;

a first differential power amplifier output connection;

a second differential power amplifier output connection; and

a power combiner configured to combine output power signals from the first differential power amplifier output connection with output power signals from the second differential power amplifier output connection into the antenna connection and into the electrical balance load connection.

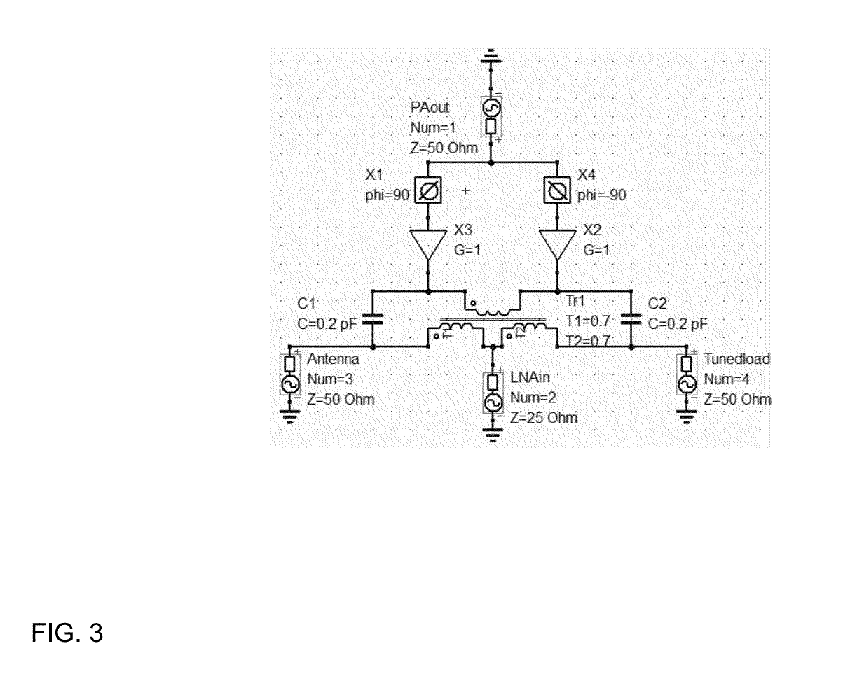

FIGS. 3 to 6 demonstrate common mode coupling issues associated with prior art duplexers.

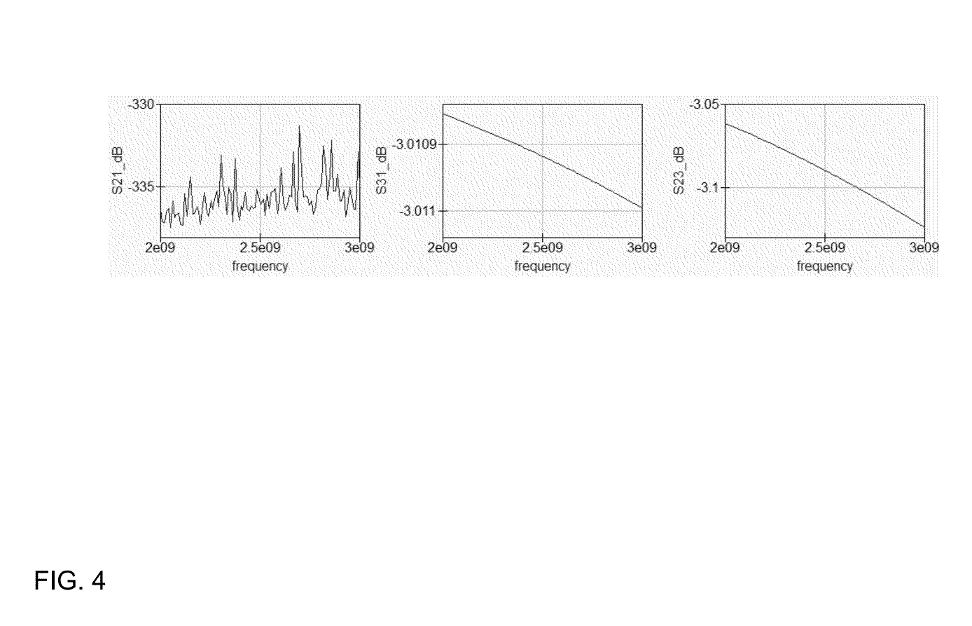

FIG. 3 shows a circuit schematic of a prior art duplexer. FIG. 4 shows simulation results for the circuit schematic of FIG. 4 according to embodiments.

In the circuit schematic of FIG. 3, port 1 with +90 and −90 degrees ideal phase shifters and amplifiers with unity gain models an ideal differential PA. A hybrid transformer isolates the differential signal from LNA port 2 as seen in the simulation result S21_dB of FIG. 4. The PA signal divides between antenna port 3 and balanced load port 4 resulting in approximately a 3 dB loss from PA to antenna as seen in the S31_dB plot of FIG. 4. Correspondingly, the signal from the antenna is divided between the LNA and balanced load resulting in approximately a 3 dB loss from the antenna to the LNA as shown in the S23_dB plot of FIG. 4. In this simulation, the antenna and balanced load is 50 Ohm, but in a real application, the isolation between ports 1 and 2 would require that either the balanced load is tuned to match the complex antenna impedance or the antenna impedance is tuned to match the balanced load. The topology can be reversed such that the PA is in port 2 and the LNA is in port 1.

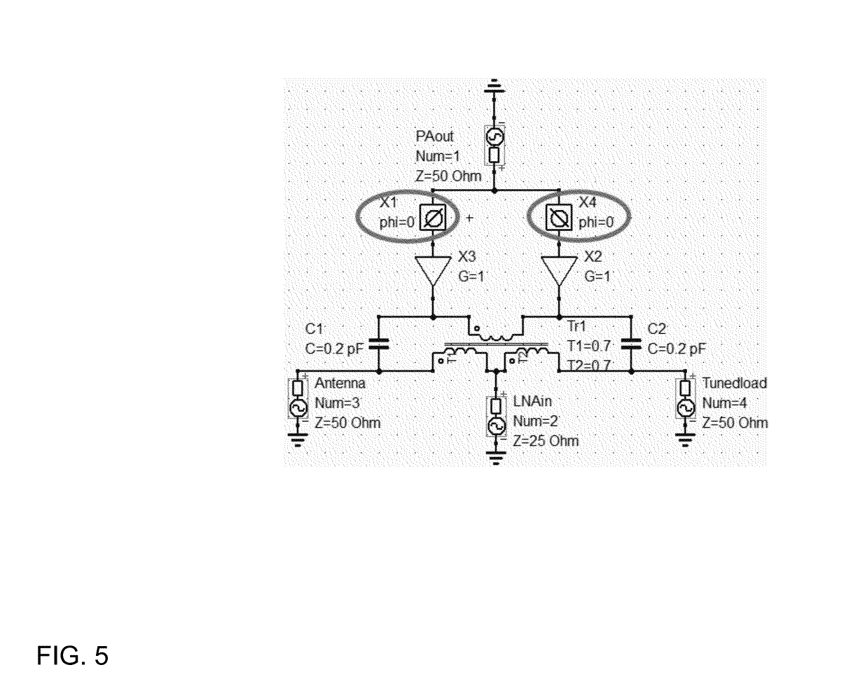

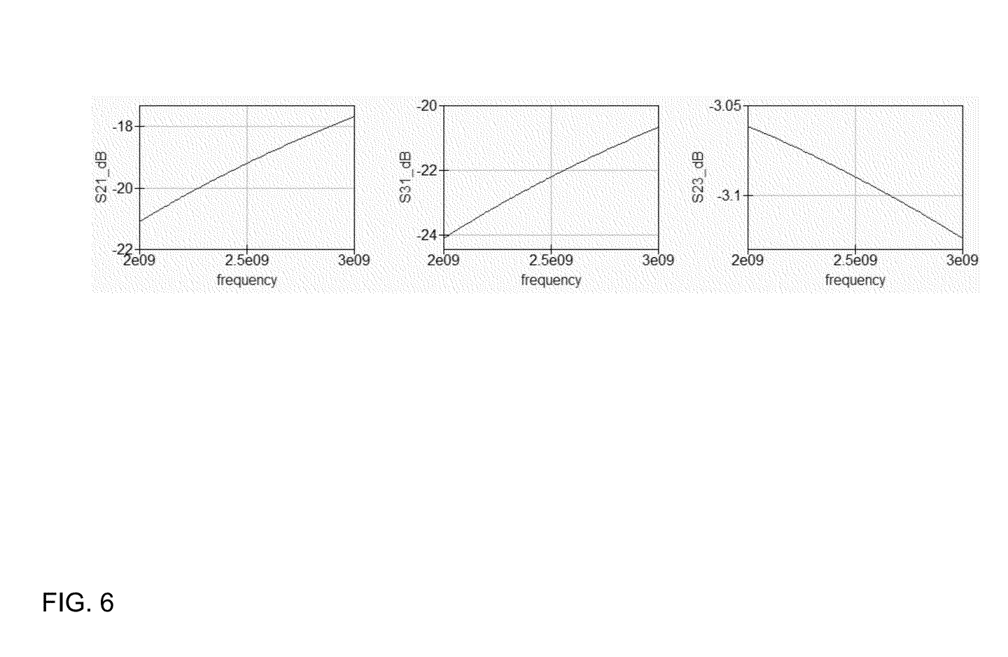

FIG. 5 shows a circuit schematic of a prior art duplexer. FIG. 6 shows simulation results for the circuit schematic of FIG. 5 according to embodiments.

In the circuit schematic of FIG. 5, the phase shift in the PA branches is set to zero (as highlighted by the oval markings), which models the common mode part of the differential PA. Capacitors C1 and C2 simulate the capacitance between the primary and secondary windings of the hybrid transformer. As can be seen from the S21_dB plot of FIG. 6, the 0.2 pF value capacitors in the example result in approximately 18 dB (i.e. poor) common mode isolation between PA and LNA.

Embodiments of the present disclosure relate to electrical balance duplexers and electrical balance duplexers topologies that reduce the PA common mode coupling issue to the LNA input(s) without the need for an additional balun for a single-ended antenna. Embodiments incorporate PA output power combination from several PA units, which is a very eligible architecture, especially for CMOS power amplifiers. Embodiments also allow switching off one or more PA units to reduce current consumption at low power levels.

Embodiments of the present disclosure combine the power from multiple PA units. Embodiments relate to electrical balance duplexers that incorporate the power combining from several PA units in order to reduce the common mode signal coupling from PA to LNA.

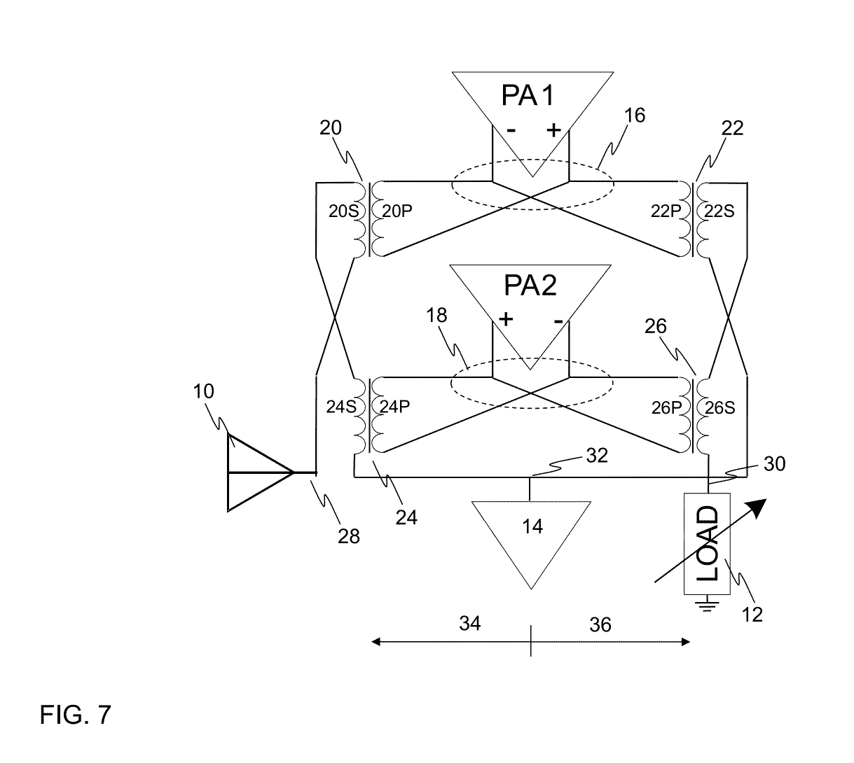

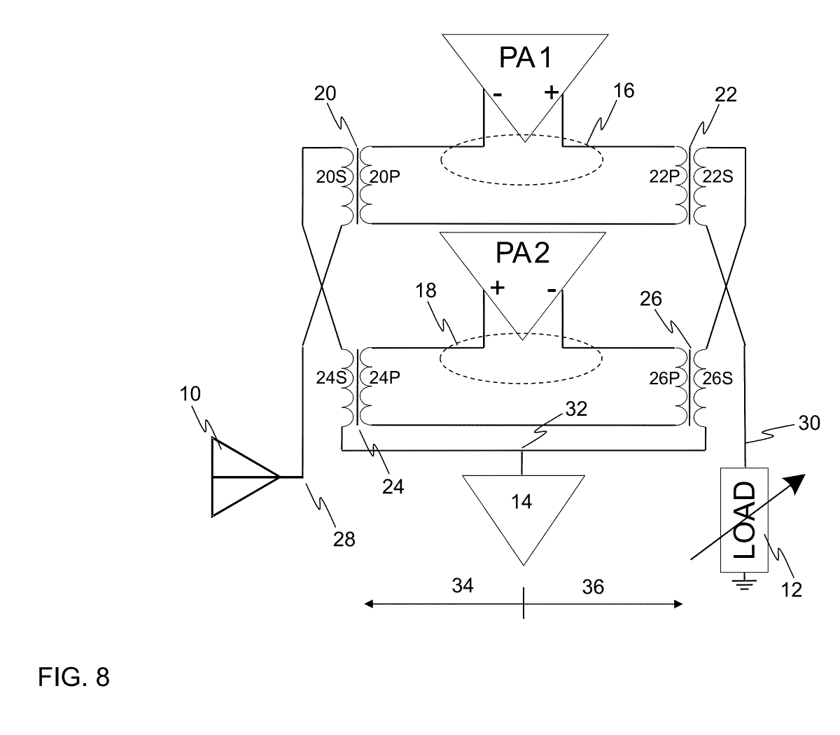

FIGS. 7 and 8 show two different topologies for electrical balance duplexers according to embodiments. In each of FIG. 7 and FIG. 8, output power is combined from two PA units which is a clear advantage especially for CMOS PAs, and also allows cancellation of the PA common model leakage due to symmetry. The power can be combined from more than two PA units and each PA unit can be switched off separately in order to lower the current consumption at lower power levels.

FIG. 7 shows an electrical balance duplexer according to embodiments. The electrical balance duplexer of FIG. 7 comprises an electrical balance load 12 having an electrical balance load connection 30, an antenna connection 28, a first differential power amplifier output connection 16, a second differential power amplifier output connection 18, and a power combiner configured to combine output power signals from the first differential power amplifier output connection 16 with output power signals from the second differential power amplifier output connection 18 into the antenna connection 28 and into the electrical balance load connection 30. In the embodiments depicted in FIG. 7, the power combiner comprises transformers 20, 22, 24, 26. In embodiments, the power combiner comprises two power combiner stages; a first power combiner stage made up of transformers 20 and 24, and a second power combiner stage made up of transformers 22 and 26. Such power combiner stages can be referred to as series-combining transformers.

FIG. 7 also depicts other components which are not comprised in the electrical balance duplexer, but which connect to the electrical balance duplexer, including an antenna 10 connected to antenna connection 28, a first differential power amplifier PA1 connected to the first differential power amplifier output connection 16 and a second differential power amplifier PA2 connected to the second differential power amplifier output connection 18.

In embodiments, antenna connection 28 comprises a single-ended antenna connection; in such embodiments, antenna 10 comprises a single-ended antenna.

In embodiments, the power combiner (for example comprised by transformers 20, 22, 24, 26) is configured to combine output power signals from the first differential power amplifier output connection 16 with output power signals from the second differential power amplifier output connection 18 in an opposite polarity into the antenna connection 28 and into the electrical balance load connection 30. Due to the opposite polarity between the combined differential output power signals, the phase difference between them will be (substantially) 180 degrees at the LNA input. Assuming that the PA units are identical and thus the common mode signal sources are also identical, then the phase difference between the capacitively coupled common mode output power signals is also 180 degrees at the LNA input. Thus, both differential and common mode output power signals cancel at the LNA input.

In embodiments, the power combiner comprises a first power combination stage 20, 24 configured to combine output power signals from the first differential power amplifier output connection with output power signals from the second differential power amplifier output connection in an opposite polarity into the antenna connection, and a second power combination stage 22, 26 configured to combine output power signals from the first differential power amplifier output connection with output power signals from the second differential power amplifier output connection in an opposite polarity into the electrical balance load connection.

In embodiments, the first and second power combination stages comprise a plurality of transformers. In such embodiments, one or more of the transformers in the plurality of transformers may comprise a hybrid transformer. The term ‘hybrid transformer’ as used herein should be taken to refer to a transformer that has more than two ports and at least two ports that are isolated from each other.

In embodiments, the electrical balance duplexer comprises a low noise amplifier input connection 32, and the power combiner is configured to combine output power signals from the first and second differential power amplifier output connections 16, 18 into the low noise amplifier input connection 32. FIG. 7 also depicts a LNA component 14 which is not comprised in the electrical balance duplexer of embodiments, but which connects to low noise amplifier input connection 32.

In embodiments, the antenna connection 28 is comprised in an antenna side 34 of the duplexer and the electrical balance load connection 30 is comprised in an electrical balance load side 36 of the duplexer. In such embodiments, the antenna side 34 is located on the opposite side of the duplexer to the electrical balance load side 36. In such embodiments, the first power combination stage comprises a first pair of transformers 20, 24 located on the antenna side 34 and the second power combination stage comprises a second pair of transformers 22, 26 located on the electrical balance load side 36.

In embodiments, the transformers 20, 24 in the first pair are electrically connected in series between the first and second differential power amplifier connections 16, 18 on the antenna side 34 and the transformers 22, 26 in the second pair are electrically connected in series between the first and second differential power amplifier connections 16, 18 on the electrical balance load side 36.

In embodiments the first power combination stage comprises first 20 and third 24 transformers, and the second power combination stage comprises second 22 and fourth transformers 26. In such embodiments, the first differential power amplifier output connection 16 comprises first and second output terminals (the terminals on the left hand side and right hand side of connection 16 respectively) and the second differential power amplifier output connection 18 comprises first and second output terminals (the terminals on the left hand side and right hand side of connection 18 respectively). In embodiments, the terminals of the primary winding 20P of the first transformer 20 are connected to the first and second output terminals of the first differential power amplifier connection 16 respectively, a first terminal (the upper terminal) of the secondary winding 20S of the first transformer 20 is connected to a first terminal (the upper terminal) of the secondary winding 24S of the third transformer 24, and a second terminal (the lower terminal) of the secondary winding 20S of the first transformer 20 is connected to the antenna connection 28. In embodiments, the terminals of the primary winding 22P of the second transformer 22 are connected to the first and second output terminals of the first differential power amplifier connection 16 respectively, a first terminal (the upper terminal) of the secondary winding 22S of the second transformer 22 is connected to a first terminal (the upper terminal) of the secondary winding 26S of the fourth transformer 26, and a second terminal (the lower terminal) of the secondary winding 22S of the second transformer 22 is connected to the second terminal (the lower terminal) of the secondary winding 24S of the third transformer 24. In embodiments, the terminals of the primary winding 24P of the third transformer 24 are connected to the first and second output terminals of the second differential power amplifier connection 18 respectively. In embodiments, the terminals of the primary winding 26P of the fourth transformer 26 are connected to the first and second output terminals of the second differential power amplifier connection 18 respectively, and the second terminal (the lower terminal) of the secondary winding 26S of the fourth transformer 26 is connected to the electrical balance load connection 30.

In embodiments, the low noise amplifier input connection 32 of FIG. 7 comprises a single-ended low noise amplifier input connection and the single-ended low noise amplifier input connection 32 is connected to the second terminal (the lower terminal) of the secondary winding 24S of the third transformer 24 and the second terminal (the lower terminal) of the secondary winding 22S of the second transformer 22.

FIG. 8 shows an electrical balance duplexer according to embodiments. The electrical balance duplexer of FIG. 8 contains similar components to the electrical balance duplexer of FIG. 7 which are labelled similarly; however, the connections between the various components in the embodiments of FIG. 8 are different to the connections in the embodiments of FIG. 7.

In the embodiments of FIG. 8, the first power combination stage comprises first 20 and third 24 transformers, and the second power combination stage comprises second 22 and fourth 26 transformers. In such embodiments, the first differential power amplifier output connection 16 comprises first and second output terminals (the terminals on the left hand side and right hand side of connection 16 respectively) and the second differential power amplifier output connection 18 comprises first and second output terminals (the terminals on the left hand side and right hand side of connection 18 respectively). In embodiments, a first terminal (the upper terminal) of the primary winding 20P of the first transformer 20 is connected to the first output terminal of the first differential power amplifier connection 16, a second terminal (the lower terminal) of the primary winding 20P of the first transformer 20 is connected to a first terminal (the lower terminal) of the primary winding 22P of the second transformer 22, a first terminal (the upper terminal) of the secondary winding 20S of the first transformer 20 is connected to a first terminal (the upper terminal) of the secondary winding 24S of the third transformer 24, and a second terminal (the lower terminal) of the secondary winding 20S of the first transformer 20 is connected to the antenna connection 28. In embodiments, a second terminal (the upper terminal) of the primary winding 22P of the second transformer 22 is connected to the second output terminal of the first differential power amplifier connection 16, a first terminal (the upper terminal) of the secondary winding 22S of the second transformer 22 is connected to a first terminal (the upper terminal) of the secondary winding 26S of the fourth transformer 26, and a second terminal (the lower terminal) of the secondary winding 22S of the second transformer 22 is connected to the electrical balance load connection 30. In embodiments, a first terminal (the upper terminal) of the primary winding 24P of the third transformer 24 is connected to the first output terminal of the second differential power amplifier connection 18, a second terminal (the lower terminal) of the primary winding 24P of the third transformer 24 is connected to a first terminal of the primary winding 26P of the fourth transformer 26, and a second terminal (the lower terminal) of the secondary winding 24S of the third transformer 24 is connected to a second terminal (the lower terminal) of the secondary winding 26S of the fourth transformer 26. In embodiments, the second terminal (the upper terminal) of the primary winding 26P of the fourth transformer 26 is connected to the second output terminal of the second differential power amplifier connection 18.

In embodiments, the low noise amplifier input connection 32 of FIG. 8 comprises a single-ended low noise amplifier input connection and the single-ended low noise amplifier input connection 32 is connected to the second terminal (the lower terminal) of the secondary winding 24S of the third transformer 24 and the second terminal (the lower terminal) of the secondary winding 26S of the fourth transformer 26.

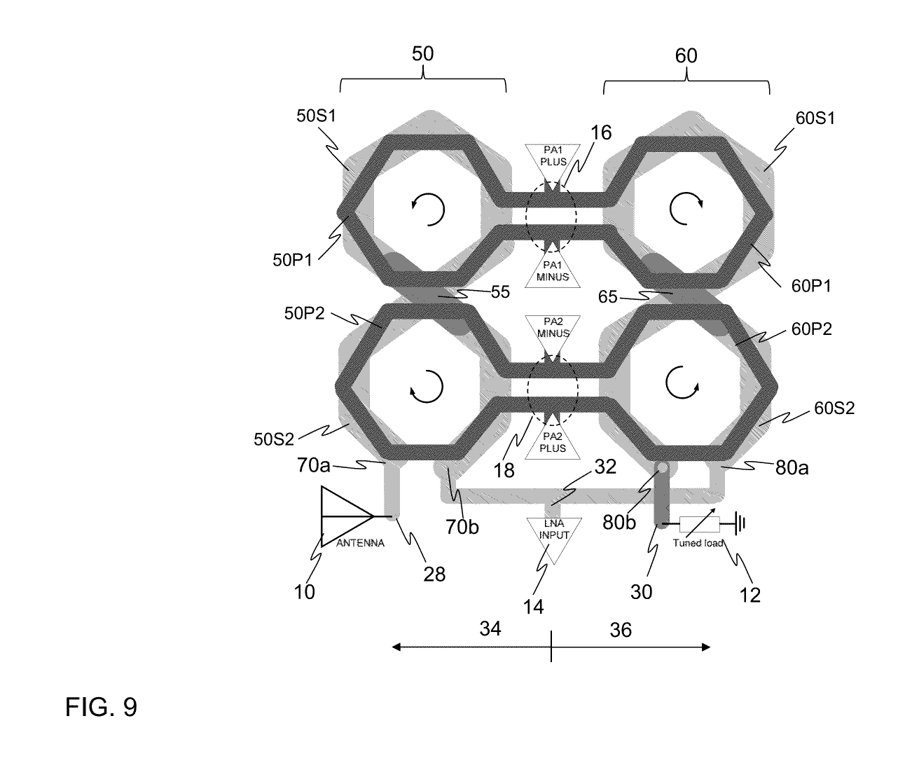

FIG. 9 shows an electrical balance duplexer according to embodiments. The electrical balance duplexer of FIG. 9 contains similar components to the electrical balance duplexers of FIGS. 7 and 8 which are labelled similarly. In these embodiments primary windings are depicted in dark grey and secondary windings are depicted in light grey.

In embodiments, the antenna connection 28 is comprised in an antenna side 34 of the duplexer and the electrical balance load connection 30 is comprised in an electrical balance load side 36 of the duplexer. In such embodiments, the antenna side 34 is located on the opposite side of the duplexer to the electrical balance load side 36. In such embodiments, the first power combination stage comprises a first distributed transformer 50 located on the antenna side 34 and the second power combination stage comprises a second distributed transformer 60 located on the electrical balance load side 36.

In embodiments, the first distributed transformer 50 is electrically connected in parallel across the first and second differential power amplifier connections 16, 18 on the antenna side 34 and the second distributed transformer 60 is electrically connected in parallel across the first and second differential power amplifier connections 16, 18 on the electrical balance load side 36.

In embodiments, the secondary winding 50S1, 50S2 of the first distributed transformer 50 forms a figure-of-eight shape on the antenna side 34 and the secondary winding 60S1, 60S2 of the second distributed transformer 60 forms a figure-of-eight shape on the electrical balance load side 36.

In embodiments, the first differential power amplifier output connection 16 comprises first and second output terminals (the upper and lower terminals of connection 16 respectively) and the second differential power amplifier output connection comprises first and second output terminals (the upper and lower terminals of connection 18 respectively). In embodiments a first part 50P1 of the primary winding 50P1, 50P2 of the first distributed transformer 50 is connected to the first and second output terminals of the first differential power amplifier connection 16 and a second part 50P2 of the primary winding 50P1, 50P2 of the first distributed transformer 50 is connected to the first and second output terminals of the second differential power amplifier connection 18. In embodiments, a first part 60P1 of the primary winding 60P1, 60P2 of the second distributed transformer 60 is connected to the first and second output terminals of the first differential power amplifier connection 16 and a second part 60P2 of the primary winding 60P1, 60P2 of the second distributed transformer 60 is connected to the first and second output terminals of the second differential power amplifier connection 18.

In embodiments, the first part 50P1 of the primary winding 50P1, 50P2 of the first distributed transformer 60 is overlaid over a first part 50S1 of the figure-of-eight shaped secondary winding 50S1, 50S2 on the antenna side 34, and the second part 50P2 of the primary winding 50P1, 50P2 of the first distributed transformer 50 is overlaid over a second part 50S2 of the figure-of-eight shaped secondary winding 50S1, 50S2 on the antenna side 34. In embodiments, the first part 60P1 of the primary winding 60P1, 60P2 of the second distributed transformer 60 is overlaid over a first part 60S1 of the figure-of-eight shaped secondary 60S1, 60S2 winding on the electrical balance load side 36, and the second part 60P2 of the primary winding 60P1, 60P2 of the second distributed transformer 60 is overlaid over a second part 60S2 of the figure-of-eight shaped secondary winding 60S1, 60S2 on the electrical balance load side 36.

In embodiments, the first part 50S1 of the figure-of-eight shaped secondary winding 50S1, 50S2 of the first distributed transformer 50 is connected to the second part 50S2 of the figure-of-eight shaped secondary winding 50S1, 50S2 of the first distributed transformer 50 by a connecting element 55. The connecting element 55 is located on a different layer to the first and second secondary winding parts 50S1, 50S2, for example on a lower layer below the figure-of-eight shaped secondary winding of the first distributed transformer 50 or on an upper layer above the figure-of-eight shaped secondary winding of the first distributed transformer 50.

In embodiments, the first part 60S1 of the figure-of-eight shaped secondary winding 60S1, 60S2 of the second distributed transformer 60 is connected to the second part 60S2 of the figure-of-eight shaped secondary winding 60S1, 60S2 of the second distributed transformer 60 by a connecting element 65. The connecting element 65 is located on a different layer to the first and second secondary winding parts 60S1, 60S2, for example on a lower layer below the figure-of-eight shaped secondary winding of the second distributed transformer 60 or on an upper layer above the figure-of-eight shaped secondary winding of the second distributed transformer 60.

In embodiments, a first terminal 70a of the secondary winding 50S1, 50S2 of the first distributed transformer 50 is connected to antenna connection 28 and a second terminal 70b of the secondary winding 50S1, 50S2 of the first distributed transformer 50 is connected to a first terminal 80a of the secondary winding of the second distributed transformer 60, and a second terminal 80b of the secondary winding 60S1, 60S2 of the second distributed transformer 60 is connected to the electrical balance load connection 30.

In embodiments, the low noise amplifier input connection 32 of FIG. 9 comprises a single-ended low noise amplifier input connection and the single-ended low noise amplifier input connection 32 is connected to the second terminal 70b of the secondary winding 50S1, 50S2 of the first distributed transformer 50 and the first terminal 80a of the secondary winding 60S1, 60S2 of the second distributed transformer 60.

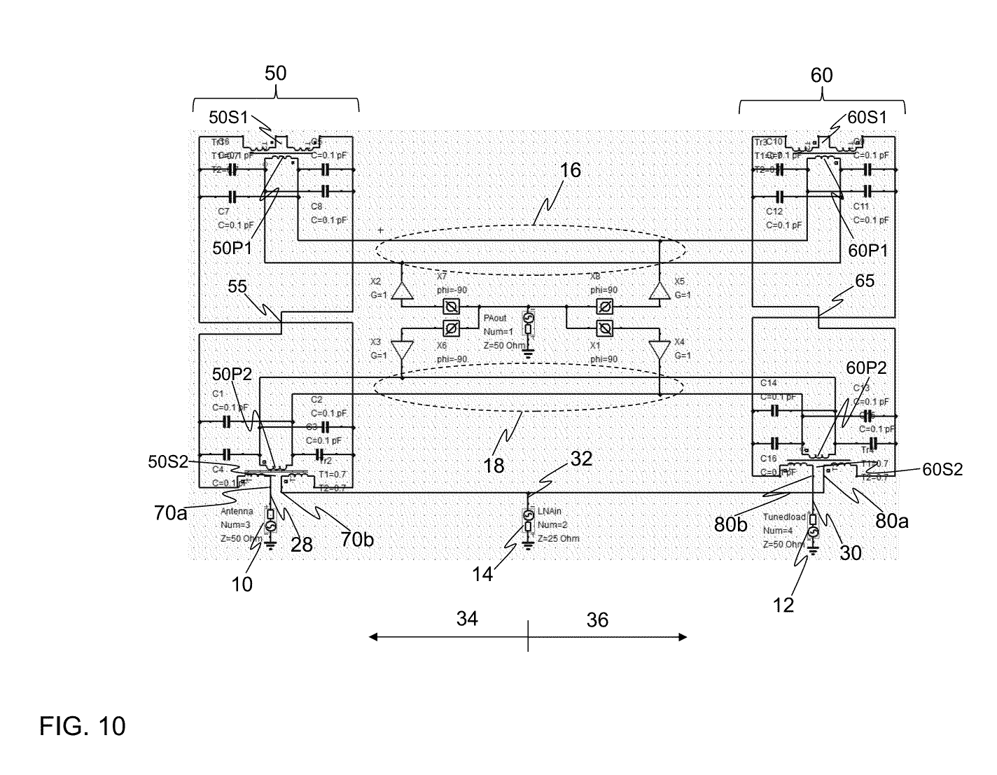

FIG. 10 shows a circuit schematic according to embodiments. FIG. 10 depicts a circuit schematic for the electrical balance duplexer of FIG. 9 with corresponding components being labelled the same in both figures.

The various capacitors in the schematic of FIG. 10 are present in order to model the parasitic capacitances between the various primary and secondary transformer windings.

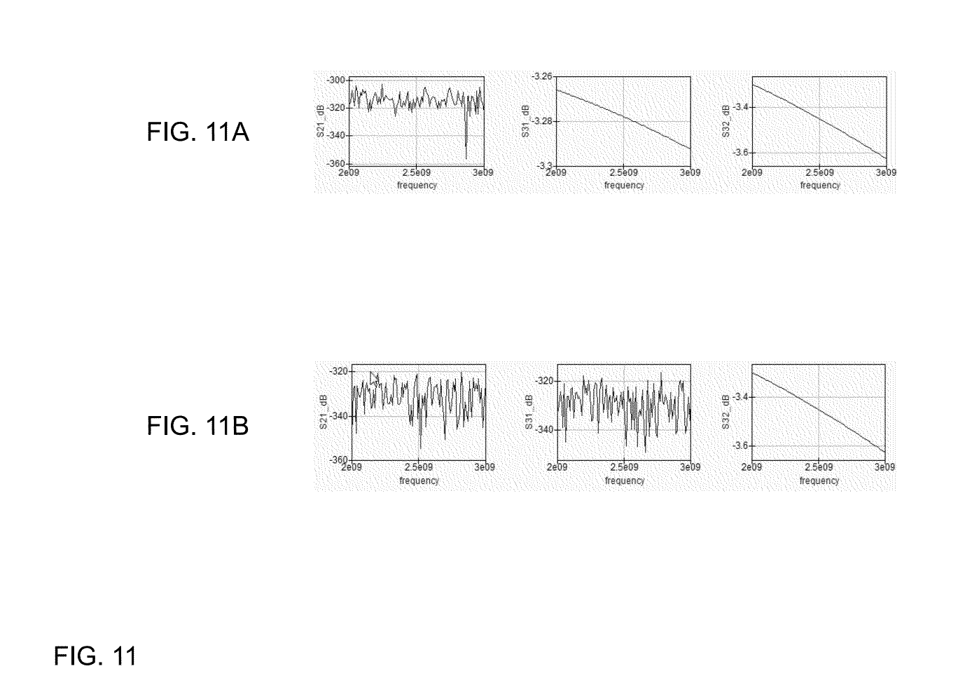

FIG. 11A shows simulation results from the circuit schematic of FIG. 10 where the phase shifts are set to model opposite polarity connection of two differential power amplifier units according to embodiments. The upper PA unit phase shift is set to +90 degrees to the upper connection and −90 degrees to the lower connection. The lower PA unit phase shift is set to −90 degrees to the upper connection and +90 degrees to the lower connection.

FIG. 11B shows simulation results from the circuit schematic of FIG. 8 where the two upper PA branch phase shifts are set to +90 degrees and the two lower PA branch phase shifts are set to −90 degrees according to embodiments. In such embodiments, it is assumed that common mode issues are identical in the two branches such that the phase difference between the branches is 180 degrees due to the opposite connection.

The duplexer topology of FIG. 9 combines PA output from two identical units with eight folded coils. Due to the symmetric capacitances and opposite polarity PA unit output connections, both the differential and the common mode signals cancel at the LNA input as seen in S21_dB plots in FIGS. 11A and 11B, respectively.

The symmetric capacitances referred to here are the symmetric amount of capacitance to the same secondary point from the PA1 plus and PA2 minus terminals, which cancels the capacitively coupled common mode signal. Similarly, there is the same amount of capacitance practically to the same point from the PA1 plus and PA1 minus terminals, so the capacitively coupled differential signals from the same PA unit is also cancelled due to symmetry.

The figure-of-eight employed shape of embodiments is very effective for power combiner purposes since adjacent loops are orientated in opposite directions, which minimizes the flux cancellation of adjacent units.

Embodiments provide the possibility of switching off one or other of the two PA units at low signal levels to reduce current consumption. When one PA unit is switched off, the common mode rejection reduces, but then also the PA output level is lower and the absolute leakage level at the LNA input is lower as well.

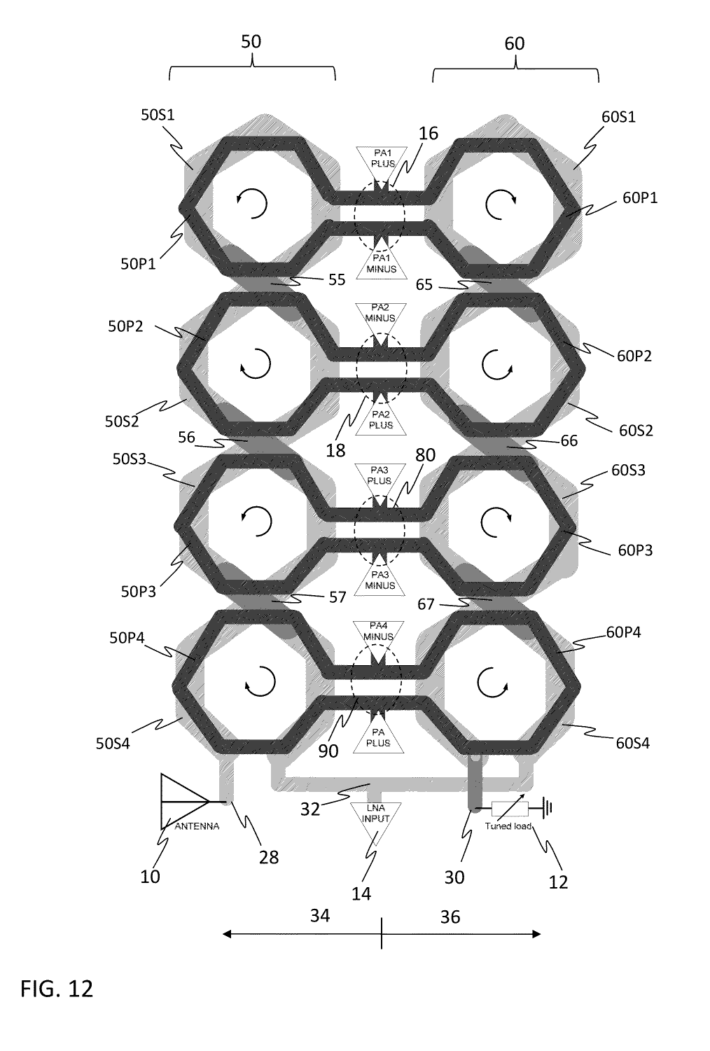

FIG. 12 shows an electrical balance duplexer according to embodiments. The electrical balance duplexer of FIG. 12 contains some similar components to the electrical balance duplexer of FIG. 9 which are labelled similarly plus some additional components. Similarly to FIG. 9, in the embodiments of FIG. 12, primary windings are depicted in dark grey and secondary windings are depicted in light grey. Such embodiments comprise a third differential power amplifier connection 80 and a fourth differential power amplifier connection 90. In such embodiments the power combiner is configured to combine output power signals from the first, second, third and fourth differential power amplifier connections 16, 18, 80, 90 into the antenna connection 28 and into the electrical balance load connection 30. In embodiments, the output power signals from the first 16 and third 80 differential power amplifier connections are combined in an opposite polarity to the output power signals from the second 18 and fourth 90 differential power amplifier connections.

FIG. 12 also depicts other components which are not comprised in the electrical balance duplexer, but which connect to the electrical balance duplexer, including an antenna 10 connected to antenna connection 28, a first differential power amplifier PA1 connected to the first differential power amplifier output connection 16, a second differential power amplifier PA2 connected to the second differential power amplifier output connection 18, a third differential power amplifier PA3 connected to the third differential power amplifier output connection 80 and a fourth differential power amplifier PA4 connected to the fourth differential power amplifier output connection 90.

In embodiments, the first distributed transformer 50 is electrically connected in parallel across the first, second, third and fourth differential power amplifier connections 16, 18, 80, 90 on the antenna side 34 and the second distributed transformer 60 is electrically connected in parallel across the first, second, third and fourth differential power amplifier connections 16, 18, 80, 90 on the electrical balance load side 36.

In embodiments the first power combination stage is configured to combine output power signals from the first 16 and third 80 differential power amplifier output connections with output power signals from the second 18 and fourth 90 differential power amplifier output connections in an opposite polarity into antenna connection 28, and the second power combination stage is configured to combine output power signals from the first 16 and third 80 differential power amplifier output connections with output power signals from the second 18 and fourth 90 differential power amplifier output connections in an opposite polarity into electrical balance load connection 30.

In embodiments, the secondary winding of the first distributed transformer 50 forms a double figure-of-eight shape (i.e. a first figure-of-eight shape located above a second figure-of-eight shape) on the antenna side 34 and the secondary winding of the second distributed transformer 60 forms a double figure-of-eight shape on the electrical balance load side 36.

In such embodiments, the first differential power amplifier output connection 16 comprises first and second output terminals (the upper and lower terminals of connection 16 respectively), the second differential power amplifier output connection comprises first and second output terminals (the upper and lower terminals of connection 18 respectively), the third differential power amplifier output connection comprises first and second output terminals (the upper and lower terminals of connection 80 respectively), and the fourth differential power amplifier output connection comprises first and second output terminals (the upper and lower terminals of connection 90 respectively).

In embodiments, a first part 50P1 of the primary winding of the first distributed transformer 50 is connected to the first and second output terminals of the first differential power amplifier connection 16, a second part 50P2 of the primary winding of the first distributed transformer 50 is connected to the first and second output terminals of the second differential power amplifier connection 18, a third part 50P3 of the primary winding of the first distributed transformer 50 is connected to the first and second output terminals of the third differential power amplifier connection 80, and a fourth part 50P4 of the primary winding of the first distributed transformer 50 is connected to the first and second output terminals of the fourth differential power amplifier connection 90.

In embodiments a first part 60P1 of the primary winding of the second distributed transformer 60 is connected to the first and second output terminals of the first differential power amplifier connection 16, a second part 60P2 of the primary winding of the second distributed transformer 60 is connected to the first and second output terminals of the second differential power amplifier connection 18, a third part 60P3 of the primary winding of the second distributed transformer 60 is connected to the first and second output terminals of the third differential power amplifier connection 80, and a fourth part 60P4 of the primary winding of the second distributed transformer 60 is connected to the first and second output terminals of the fourth differential power amplifier connection 90.

In embodiments, the first part 50P1 of the primary winding of the first distributed transformer 60 is overlaid over a first part 50S1 of the double figure-of-eight shaped secondary winding on the antenna side 34, the second part 50P2 of the primary winding of the first distributed transformer 50 is overlaid over a second part 50S2 of the double figure-of-eight shaped secondary winding on the antenna side 34, the third part 50P3 of the primary winding of the first distributed transformer 60 is overlaid over a third part 50S3 of the double figure-of-eight shaped secondary winding on the antenna side 34, and the fourth part 50P4 of the primary winding of the first distributed transformer 50 is overlaid over a fourth part 50S4 of the double figure-of-eight shaped secondary winding on the antenna side 34.

In embodiments, the first part 60P1 of the primary winding of the second distributed transformer 60 is overlaid over a first part 60S1 of the double figure-of-eight shaped secondary winding on the electrical balance load side 36, the second part 60P2 of the primary winding of the second distributed transformer 60 is overlaid over a second part 60S2 of the double figure-of-eight shaped secondary winding on the electrical balance load side 36, the third part 60P3 of the primary winding of the second distributed transformer 60 is overlaid over a third part 60S3 of the double figure-of-eight shaped secondary winding on the electrical balance load side 36, and the fourth part 60P4 of the primary winding of the second distributed transformer 60 is overlaid over a fourth part 60S4 of the double figure-of-eight shaped secondary winding on the electrical balance load side 36.

In embodiments, the first part 50S1 of the double figure-of-eight shaped secondary winding of the first distributed transformer 50 is connected to the second part 50S2 of the double figure-of-eight shaped secondary winding of the first distributed transformer 50 by a connecting element 55. In embodiments, the first part 60S1 of the double figure-of-eight shaped secondary winding of the second distributed transformer 60 is connected to the second part 60S2 of the double figure-of-eight shaped secondary winding of the second distributed transformer 60 by a connecting element 65.

In embodiments, the second part 50S2 of the double figure-of-eight shaped secondary winding of the first distributed transformer 50 is connected to the third part 50S3 of the double figure-of-eight shaped secondary winding of the first distributed transformer 50 by a connecting element 56. In embodiments, the second part 60S2 of the double figure-of-eight shaped secondary winding of the second distributed transformer 60 is connected to the third part 60S2 of the double figure-of-eight shaped secondary winding of the second distributed transformer 60 by a connecting element 66.

In embodiments, the third part 50S3 of the double figure-of-eight shaped secondary winding of the first distributed transformer 50 is connected to the fourth part 50S4 of the double figure-of-eight shaped secondary winding of the first distributed transformer 50 by a connecting element 57. In embodiments, the third part 60S3 of the double figure-of-eight shaped secondary winding of the second distributed transformer 60 is connected to the fourth part 60S4 of the double figure-of-eight shaped secondary winding of the second distributed transformer 60 by a connecting element 67.

As can be seen from FIG. 12, the fourth part of the secondary winding on the antennas side 34 of the first distributed transformer 50 connects to antenna connection 28 and the fourth part of the secondary winding on the electrical balance load side 36. and the fourth part of the secondary winding on the electrical balance load side 36 of the first distributed transformer 60 connects to electrical balance load connection 30.

In embodiments, the PA output power can be combined from more than two differential PA units, for example as in FIG. 12. In the case of a transceiver, the PA output power can be thought of as TX power, in which case, the total amplified TX power is achieved by amplifying the TX signal in parallel PA units and summing their output powers.

FIG. 9 described above illustrates power combination from two differential units and FIG. 12 described above illustrates power combination from four differential units. Other embodiments allow combination from more than four differential units; extension of the embodiments of FIG. 12 to embodiments with higher numbers of differential PAs (i.e. more than two pairs of differential PAs) will be clear to one skilled in the art and will not be described in further detail herein.

In embodiments, any of the differential PAs can be switched off separately at lower powers. This is particularly useful in relation to RF transceivers because as RF transceivers are required to work over large power ranges, for example a basestation may require TX power to be anything between −55 dBm to +24 dBm depending on the connection between the phone antenna and basestation antenna. If nothing is done to the PA (for example bias is kept constant), the PA consumes as much battery current at low power as at high powers. However, switching off a PA unit as per embodiments reduces current consumption.

In some embodiments, a PA can be powered down by setting a relevant bias to zero. In other embodiments, a PA can be powered down with the use of one or more bypass switches.

In embodiments, the electrical balance duplexer of embodiments comprises one or more bypass switches configured to, in response to receipt of a control signal, bypass the power from one or more of the first, second, third and fourth differential power amplifier connections, 16, 18, 80, 90. In embodiments, the one or more bypass switches are comprised in the power combiner.

The electrical balance duplexers of embodiments reduce the PA common mode coupling issue to the LNA input without the need for an additional balun for a single-end antenna or single-end PA. Also, embodiments incorporate PA output power combination from several differential PA units, which is a very suitable architecture especially for CMOS power amplifiers. When employing embodiments, an additional balun is not needed since embodiments incorporate electrical balance duplexing with PA power combination (which is usually desirable in order to get enough output power from low break-down voltage CMOS PAs). Embodiments also allow switching off of PA units to reduce current consumption at low power levels.

Embodiments enable a differential PA without the need for an additional balun in the PA side, or in the antenna side. Embodiments enable power combination from several PA units.

In embodiments, at least one of the first, second, third and fourth differential power amplifier connections 16, 18, 80, 90 comprises a connection for a complementary metal oxide semiconductor (CMOS) differential power amplifier.

Embodiments comprise a radio frequency (RF) transceiver comprising one or more electrical balance duplexers according to embodiments described herein.

Embodiments comprise a device comprising one or more electrical balance duplexers according to embodiments described herein. The device may for example comprise a user equipment such as a mobile (or ‘cellular’) telephone.

Embodiments comprise a radio-frequency semiconductor integrated circuit (RFIC) comprising one or more electrical balance duplexers according to embodiments described herein.

Embodiments comprise a chipset comprising one or more electrical balance duplexers according to embodiments described herein.

Embodiments comprise a method of operating an electrical balance duplexer according to embodiments described herein.

Embodiments comprise a method of manufacturing an electrical balance duplexer, the method comprising providing an electrical balance load having an electrical balance load connection, providing an antenna connection, providing a first differential power amplifier output connection, providing a second differential power amplifier output connection, and providing a power combiner configured to combine output power signals from the first differential power amplifier output connection with output power signals from the second differential power amplifier output connection into the antenna connection and into the electrical balance load connection.

The differential topology of embodiments is well suited for power combination from several differential units. The differential topology of embodiments improves isolation to other circuitry (i.e. not only to the RX path) and improves stability, cancels harmonics, etc.

Multimode cellular transceivers cover several frequency bands, and in conventional architectures each band has a separate duplex filter. Duplex filters are expensive and physically large components. Integrated electrical balance duplexers as enabled by embodiments described herein can cover several bands and are thus highly attractive for low cost commercial devices.

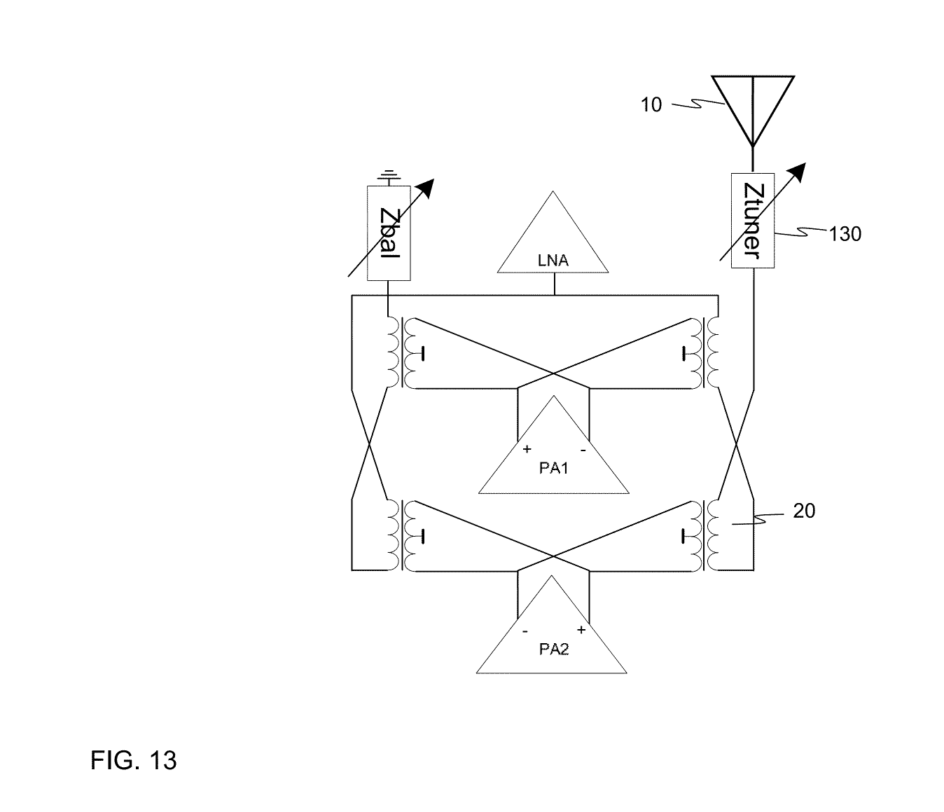

FIG. 13 shows an electrical balance duplexer according to embodiments. The electrical balance duplexer of FIG. 13 contains similar components to the electrical balance duplexer of FIG. 7, but with an additional impedance tuning element 130 (denoted ‘Ztuner’ in FIG. 13) located between antenna 10 and transformer 20. In some embodiments, the antenna port impedance is balanced by the tuner to the (fixed) balance port impedance; however, in other embodiments, fine tuning may be required in the electrical balance load (denoted ‘Zbal’ in FIG. 13).

In embodiments, the electrical balance duplexer comprises an impedance tuning element connected between the antenna connection and the power combiner.

The above embodiments are to be understood as illustrative examples of the invention. Further embodiments of the invention are envisaged.

In embodiments described above, a balanced load is an integral part of the electrical balance duplexer. In alternative embodiments, the balanced node can be a separate component to the duplexer.

Embodiments comprise an electrical balance duplexer comprising:

an electrical balance load connection;

an antenna connection;

a first differential power amplifier output connection;

a second differential power amplifier output connection; and

a power combiner configured to combine output power signals from the first differential power amplifier output connection with output power signals from the second differential power amplifier output connection into the antenna connection and into the electrical balance load connection.

It is to be understood that any feature described in relation to any one embodiment may be used alone, or in combination with other features described, and may also be used in combination with one or more features of any other of the embodiments, or any combination of any other of the embodiments. Furthermore, equivalents and modifications not described above may also be employed without departing from the scope of the invention, which is defined in the accompanying claims.

### LIST OF ABBREVIATIONS AND ACRONYMS

CMOS complementary metal oxide semiconductor
CMRR common mode rejection ratio
dB decibel
dBm power referenced to one milliwatt
DSP digital signal processing
LNA low noise amplifier
PA power amplifier
RF radio frequency
RFIC radio-frequency semiconductor integrated circuit
RX receiver
TX transmitter

1. An electrical balance duplexer comprising:
an electrical balance load having an electrical balance load connection;
an antenna connection;
a first differential power amplifier output connection;
a second differential power amplifier output connection; and
a power combiner configured to combine output power signals from the first differential power amplifier output connection with output power signals from the second differential power amplifier output connection into the antenna connection and into the electrical balance load connection.

2. An electrical balance duplexer according to claim 1, wherein the power combiner is configured to combine output power signals from the first differential power amplifier output connection with output power signals from the second differential power amplifier output connection in an opposite polarity into the antenna connection and into the electrical balance load connection.

3. An electrical balance duplexer according to claim 1, wherein the power combiner comprises:
a first power combination stage configured to combine output power signals from the first differential power amplifier output connection with output power signals from the second differential power amplifier output connection in an opposite polarity into the antenna connection; and
a second power combination stage configured to combine output power signals from the first differential power amplifier output connection with output power signals from the second differential power amplifier output connection in an opposite polarity into the electrical balance load connection.

4. An electrical balance duplexer according to claim 3, wherein the first and second power combination stages comprise a plurality of transformers.

5. An electrical balance duplexer according to claim 4, wherein one or more of the transformers in the plurality of transformers comprises a hybrid transformer.

6. An electrical balance duplexer according to claim 1, comprising a low noise amplifier input connection,
wherein the power combiner is configured to combine output power signals from the first and second differential power amplifier output connections into the low noise amplifier input connection.

7. An electrical balance duplexer according to claim 1, wherein the antenna connection comprises a single-ended antenna connection.

8. An electrical balance duplexer according to claim 3,
wherein the antenna connection is comprised in an antenna side of the duplexer and the electrical balance load connection is comprised in an electrical balance load side of the duplexer, the antenna side being located on the opposite side of the duplexer to the electrical balance load side, and
wherein the first power combination stage comprises a first pair of transformers located on the antenna side and a second pair of transformers located on the electrical balance load side.

9. An electrical balance duplexer according to claim 8, wherein the transformers in the first pair are electrically connected in series between the first and second differential power amplifier connections on the antenna side and the transformers in the second pair are electrically connected in series between the first and second differential power amplifier connections on the electrical balance load side.

10. An electrical balance duplexer according to claim 3, wherein the first power combination stage comprises first and third transformers, and the second power combination stage comprises second and fourth transformers,
wherein the first differential power amplifier output connection comprises first and second output terminals,
wherein the second differential power amplifier output connection comprises first and second output terminals,
wherein the terminals of the primary winding of the first transformer are connected to the first and second output terminals of the first differential power amplifier connection respectively, a first terminal of the secondary winding of the first transformer is connected to a first terminal of the secondary winding of the third transformer, and a second terminal of the secondary winding of the first transformer is connected to the antenna connection,
wherein the terminals of the primary winding of the second transformer are connected to the first and second output terminals of the first differential power amplifier connection respectively, a first terminal of the secondary winding of the second transformer is connected to a first terminal of the secondary winding of the fourth transformer, and a second terminal of the secondary winding of the second transformer is connected to the second terminal of the secondary winding of the third transformer,
wherein the terminals of the primary winding of the third transformer are connected to the first and second output terminals of the second differential power amplifier connection respectively, and
wherein the terminals of the primary winding of the fourth transformer are connected to the first and second output terminals of the second differential power amplifier connection respectively, and the second terminal of the secondary winding of the fourth transformer is connected to the electrical balance load connection.

11. (canceled)

12. An electrical balance duplexer according to claim 3, wherein the first power combination stage comprises first and third transformers, and the second power combination stage comprises second and fourth transformers,
wherein the first differential power amplifier output connection comprises first and second output terminals,
wherein the second differential power amplifier output connection comprises first and second output terminals,
wherein a first terminal of the primary winding of the first transformer is connected to the first output terminal of the first differential power amplifier connection, a second terminal of the primary winding of the first transformer is connected to a first terminal of the primary winding of the second transformer, a first terminal of the secondary winding of the first transformer is connected to a first terminal of the secondary winding of the third transformer, and a second terminal of the secondary winding of the first transformer is connected to the antenna connection,
wherein a second terminal of the primary winding of the second transformer is connected to the second output terminal of the first differential power amplifier connection, a first terminal of the secondary winding of the second transformer is connected to a first terminal of the secondary winding of the fourth transformer, and a second terminal of the secondary winding of the second transformer is connected to the electrical balance load connection,
wherein a first terminal of the primary winding of the third transformer is connected to the first output terminal of the second differential power amplifier connection, a second terminal of the primary winding of the third transformer is connected to a first terminal of the primary winding of the fourth transformer, and a second terminal of the secondary winding of the third transformer is connected to a second terminal of the secondary winding of the fourth transformer, and
wherein the second terminal of the primary winding of the fourth transformer is connected to the second output terminal of the second differential power amplifier connection.

13. (canceled)

14. An electrical balance duplexer according to claim 3,
wherein the antenna connection is comprised in an antenna side of the duplexer and the electrical balance load connection is comprised in an electrical balance load side of the duplexer, the antenna side being located on the opposite side of the duplexer to the electrical balance load side, and
wherein the first power combination stage comprises a first distributed transformer located on the antenna side and the second power combination stage comprises a second distributed transformer located on the electrical balance load side.

15. A duplexer according to claim 14, wherein the first distributed transformer is electrically connected in parallel across the first and second differential power amplifier connections on the antenna side and the second distributed transformer is electrically connected in parallel across the first and second differential power amplifier connections on the electrical balance load side.

16. An electrical balance duplexer according to claim 14, wherein the secondary winding of the first distributed transformer forms a figure-of-eight shape on the antenna side and the secondary winding of the second distributed transformer forms a figure-of-eight shape on the electrical balance load side.

17. An electrical balance duplexer according to claim 14,
wherein the first differential power amplifier output connection comprises first and second output terminals,
wherein the second differential power amplifier output connection comprises first and second output terminals,
wherein a first part of the primary winding of the first distributed transformer is connected to the first and second output terminals of the first differential power amplifier connection and a second part of the primary winding of the first distributed transformer is connected to the first and second output terminals of the second differential power amplifier connection, and
wherein a first part of the primary winding of the second distributed transformer is connected to the first and second output terminals of the first differential power amplifier connection and a second part of the primary winding of the second distributed transformer is connected to the first and second output terminals of the second differential power amplifier connection.

18. (canceled)

19. An electrical balance duplexer according to claim 14, wherein a first terminal of the secondary winding of the first distributed transformer is connected to the antenna connection and a second terminal of the secondary winding of the first distributed transformer is connected to a first terminal of the secondary winding of the second distributed transformer, and
wherein a second terminal of the secondary winding of the second distributed transformer is connected to the electrical balance load connection.

20. A duplexer according to claim 19, wherein the low noise amplifier input connection comprises a single-ended low noise amplifier input connection and the single-ended low noise amplifier input connection is connected to the second terminal of the secondary winding of the first distributed transformer and the first terminal of the secondary winding of the second distributed transformer.

21-28. (canceled)

29. A radio-frequency semiconductor integrated circuit (RFIC) comprising one or more electrical balance duplexers according to claim 1.

30-31. (canceled)

32. A method of manufacturing an electrical balance duplexer, the method comprising:
providing an electrical balance load having an electrical balance load connection;
providing an antenna connection;
providing a first differential power amplifier output connection;
providing a second differential power amplifier output connection; and
providing a power combiner configured to combine output power signals from the first differential power amplifier output connection with output power signals from the second differential power amplifier output connection into the antenna connection and into the electrical balance load connection.

33. (canceled)

34. An electrical balance duplexer comprising:
an electrical balance load connection;
an antenna connection;
a first differential power amplifier output connection;
a second differential power amplifier output connection; and
a power combiner configured to combine output power signals from the first differential power amplifier output connection with output power signals from the second differential power amplifier output connection into the antenna connection and into the electrical balance load connection.
